(19) United States
(12) Patent Application Publication
(10) Pub. No.: US 2025/0318254 A1
(43) Pub. Date: Oct. 9, 2025

(54) SEMICONDUCTOR DEVICE

(71) Applicant: FUJI ELECTRIC CO., LTD., Kanagawa (JP)

(72) Inventors: Toshiki SUZUKI, Matsumoto-city (JP); Tatsuya NAITO, Matsumoto-city (JP); Makoto SHIMOSAWA, Matsumoto-city (JP); Kazuki KAMIMURA, Matsumoto-city (JP); Toshiyuki MATSUI, Matsumoto-city (JP)

(21) Appl. No.: 19/245,388

(22) Filed: Jun. 22, 2025

Related U.S. Application Data
(63) Continuation of application No. PCT/JP2024/018628, filed on May 21, 2024.

(30) Foreign Application Priority Data
Jul. 6, 2023 (JP) 2023-111372

(51) Int. Cl. H10D 84/00; H10D 8/00; H10D 12/00; H10D 62/10; H10D 64/23; H10D 64/27

(52) U.S. Cl. CPC H10D 84/161; H10D 8/422; H10D 12/415; H10D 12/481; H10D 62/103; H10D 62/126; H10D 64/232; H10D 64/519

(57) ABSTRACT

Provided is a semiconductor device including: a drift region of a first conductivity type which is provided in a semiconductor substrate; an emitter region of the first conductivity type which is provided at a front surface of the semiconductor substrate, and which has a doping concentration higher than that of the drift region; a plurality of trench portions which are provided above the drift region; a trench contact portion which is provided in a mesa portion between the plurality of trench portions; and a plug region of a second conductivity type which is provided in contact with a lower end of the trench contact portion. The trench contact portion may have a main trench contact which extends in a trench extension direction in a top view, and a sub-trench contact which extends from the main trench contact in a direction different from the trench extension direction in the top view.

The contents of the following patent application(s) are incorporated herein by reference:
NO. 2023-111372 filed in JP on Jul. 6, 2023
NO. PCT/JP2024/018628 filed in WO on May 21, 2024.

### BACKGROUND

### 1. Technical Field

The present invention relates to a semiconductor device.

### 2. Related Art

Patent Document 1 discloses a semiconductor device having a trench contact.

### PRIOR ART DOCUMENTS

### Patent Documents

Patent Document 1: International Publication No. WO 2020-213254
Patent Document 2: Japanese Patent Application Publication No. 2020-115550

### BRIEF DESCRIPTION OF THE DRAWINGS

FIG. 1A is a view showing an example of an upper surface of a semiconductor device 100.

FIG. 1B is a view showing an example of a cross section a-a′ of the semiconductor device 100.

FIG. 1C is a view showing an example of a cross section b-b′ of the semiconductor device 100.

FIG. 1D is a view showing an example of a cross section c-c′ of the semiconductor device 100.

FIG. 1E is a view showing an example of a cross section d-d′ of the semiconductor device 100. g

FIG. 2 is a view showing a modified example of the upper surface of the semiconductor device 100.

FIG. 3 is a view showing a modified example of the upper surface of the semiconductor device 100.

FIG. 4A is a view showing a modified example of the upper surface of the semiconductor device 100.

FIG. 4B is a view showing an example of a cross section e-e′ of the semiconductor device 100.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as an “upper” side, and another side is referred to as a “lower” side. One surface of two principal surfaces of a substrate, a layer or another member is referred to as an upper surface, and another surface is referred to as a lower surface. “Upper”, “lower”, “front”, and “back” directions are not limited to a direction of gravity, or a direction of an attachment to a substrate or the like when a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicating the height direction with respect to the ground. It should be noted that a +Z axis direction and a −Z axis direction are directions opposite to each other. If a Z axis direction is described without describing the signs, it means that the direction is parallel to a +Z axis and a −Z axis.

In the present specification, a surface parallel to the upper surface of the semiconductor substrate is referred to as the XY surface, and an orthogonal axis parallel to the upper surface and the lower surface of the semiconductor substrate is referred to as the X axis and the Y axis. In addition, an axis perpendicular to the upper surface and the lower surface of the semiconductor substrate is referred to as the Z axis. The depth direction of a semiconductor substrate may be referred to as the Z axis. It should be noted that, as used in the present specification, the view of the semiconductor substrate in the Z axis direction is referred to as a planar view. In addition, in the present specification, a direction parallel to the upper surface and the lower surface of the semiconductor substrate may be referred to as a horizontal direction, including an X axis direction and a Y axis direction.

Each Example shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each Example respectively have opposite polarities.

A case where a term such as “same” or “equal” is used in the present specification may include a case where an error due to a variation in manufacturing or the like is included. The error is, for example, within 10%.

In the present specification, a conductivity type of a doping region doped with impurities is described as the P type or the N type. In the present specification, the impurities may particularly mean either donors of the N type or acceptors of the P type, and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state.

In the present specification, a description of a P+ type or an N+ type means a higher doping concentration than that of the P type or the N type, and a description of a P− type or an N− type means a lower doping concentration than that of the P type or the N type.

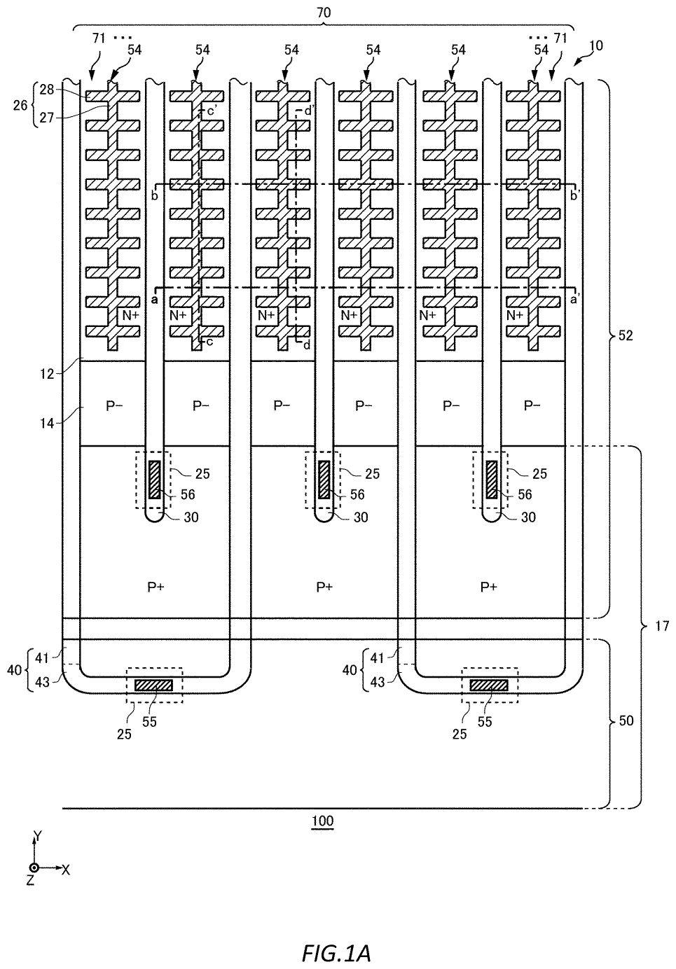

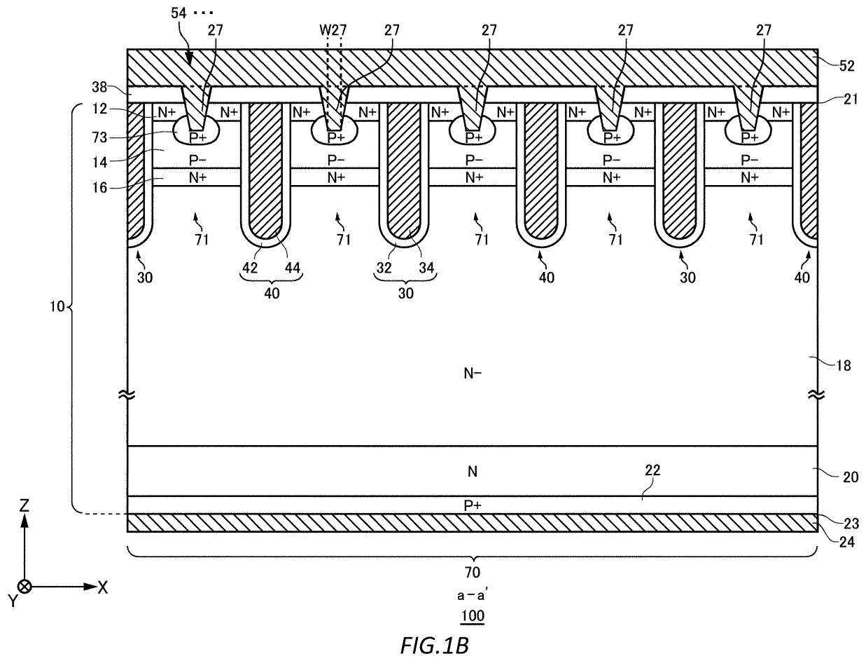

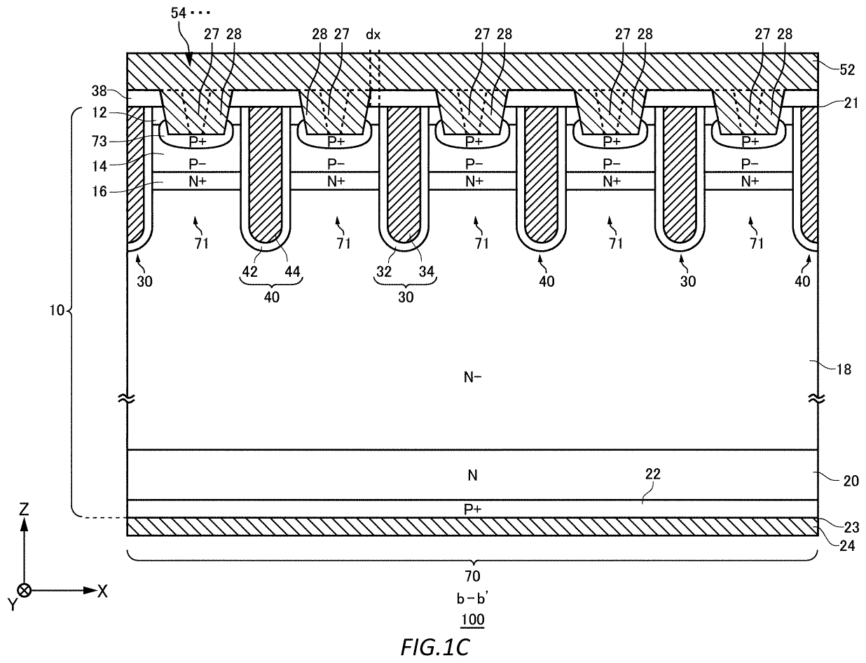

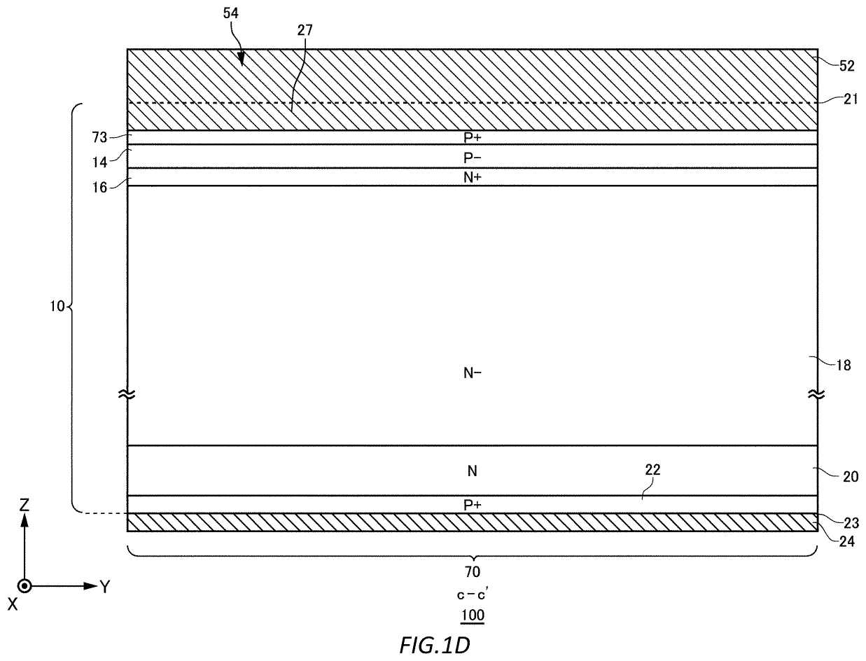

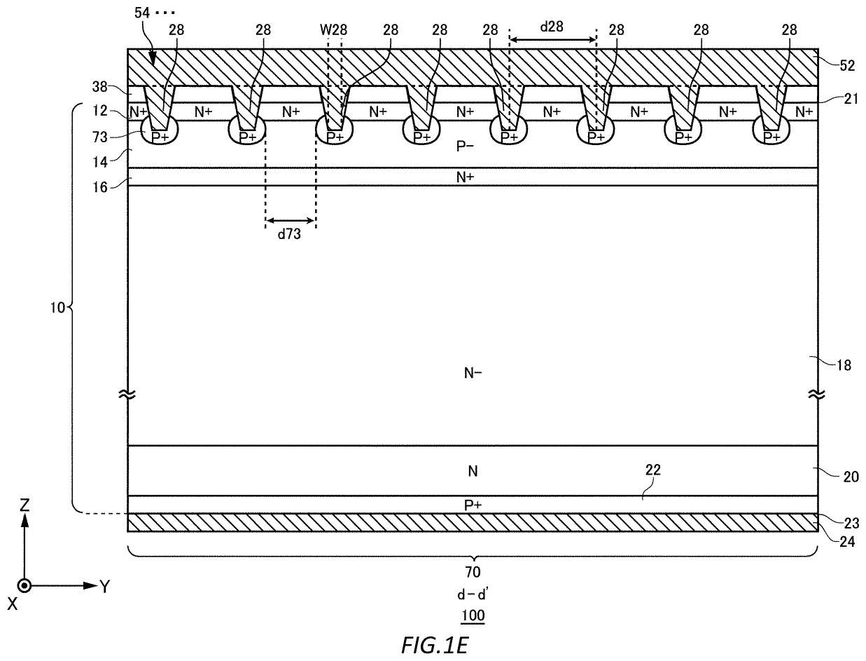

FIG. 1A shows an example of an upper surface of a semiconductor device 100. The semiconductor device 100 in the present example is a semiconductor chip including at least a transistor portion 70. For example, the semiconductor device 100 is a reverse conducting IGBT (RC-IGBT).

The transistor portion 70 is a region obtained by projecting a collector region 22 provided on a back surface side of a semiconductor substrate 10 onto an upper surface of the semiconductor substrate 10. The collector region 22 will be described below. The transistor portion 70 includes a transistor such as an IGBT.

FIG. 1A shows a surrounding region of a chip end portion, which is an edge side of the semiconductor device 100, and the other regions are omitted. For example, an edge termination structure portion may be provided in a region on a negative side in the Y axis direction in the semiconductor device 100 in the present example. The edge termination structure portion reduces electric field strength on an upper surface side of the semiconductor substrate 10. The edge termination structure portion has, for example, a guard ring, a field plate, a RESURF, and a structure combining these. It should be noted that although the present example describes an edge on the negative side in the Y axis direction for convenience, the same applies to other edges of the semiconductor device 100. The edge termination structure portion may be provided so as to enclose an active region including the transistor portion 70.

The semiconductor substrate 10 may be a silicon substrate, may be a silicon carbide substrate, or may be a nitride semiconductor substrate such as gallium nitride, or the like. The semiconductor substrate 10 in the present example is the silicon substrate.

The semiconductor device 100 in the present example includes a gate trench portion 40, a dummy trench portion 30, an emitter region 12, a base region 14, and a well region 17, at a front surface 21 of the semiconductor substrate 10. The front surface 21 will be described below. In addition, the semiconductor device 100 in the present example includes an emitter electrode 52 and a gate metal layer 50 which are provided above the front surface 21 of the semiconductor substrate 10.

The emitter electrode 52 is provided above the gate trench portion 40, the dummy trench portion 30, the emitter region 12, the base region 14, and the well region 17. In addition, the gate metal layer 50 is provided above a connection portion 25 and the well region 17.

The emitter electrode 52 and the gate metal layer 50 are formed of a material containing metal. At least a partial region of the emitter electrode 52 may be formed of metal such as aluminum (Al), or of a metal alloy such as an aluminum-silicon alloy (AlSi) or an aluminum-silicon-copper alloy (AlSiCu). At least a partial region of the gate metal layer 50 may be formed of metal such as aluminum (Al), or of a metal alloy such as an aluminum-silicon alloy (AlSi) or an aluminum-silicon-copper alloy (AlSiCu). The emitter electrode 52 and the gate metal layer 50 may include a barrier metal layer formed of titanium, a titanium compound, or the like under a region formed of aluminum and the like. The emitter electrode 52 and the gate metal layer 50 are provided separately from each other.

The emitter electrode 52 and the gate metal layer 50 are provided above the semiconductor substrate 10, with an interlayer dielectric film 38 sandwiched therebetween. The interlayer dielectric film 38 is omitted in FIG. 1A. A contact hole 54, a contact hole 55, and a contact hole 56 are provided to pass through the interlayer dielectric film 38.

The contact hole 55 electrically connects the gate metal layer 50 to a gate conductive portion in the transistor portion 70 through the connection portion 25. A plug layer formed of tungsten or the like may be formed inside the contact hole 55.

The contact hole 56 connects the emitter electrode 52 to a dummy conductive portion in the dummy trench portion 30. A plug layer formed of tungsten or the like may be formed inside the contact hole 56.

The connection portion 25 is connected to a metal layer on a front surface side such as the emitter electrode 52 or the gate metal layer 50. In an example, the connection portion 25 is provided between the gate metal layer 50 and the gate conductive portion. The connection portion 25 in the present example may be provided to extend in the X axis direction, and is electrically connected to the gate conductive portion. The connection portion 25 may also be provided between the emitter electrode 52 and the dummy conductive portion. The connection portion 25 is formed of a conductive material such as polysilicon doped with an impurity. The connection portion 25 in the present example is polysilicon (N+) doped with an impurity of the N type. The connection portion 25 is provided above the front surface 21 of the semiconductor substrate 10 via a dielectric film such as an oxide film or the like.

The front surface 21 of the semiconductor substrate 10 is provided with a plurality of trench portions which extend in a predetermined direction (the Y axis direction in the present example), and are arrayed in a predetermined direction (the X axis direction in the present example). The plurality of trench portions have the gate trench portion 40 to which a gate potential is applied, and the dummy trench portion 30 to which a potential different from the gate potential is applied.

The gate trench portion 40 is an example of the plurality of trench portions extending in a predetermined extension direction on a front surface 21 side of the semiconductor substrate 10. The gate trench portions 40 are arrayed at a predetermined interval along a predetermined array direction (the X axis direction in the present example). The gate trench portion 40 in the present example may have: two extension parts 41 which extend along the extension direction (the Y axis direction in the present example) that is parallel to the front surface 21 of the semiconductor substrate 10 and that is perpendicular to the array direction; and a connection part 43 which connects the two extension parts 41.

It is preferable that at least a part of the connection part 43 is formed in a curved shape. By connecting end portions of the two extension parts 41 of the gate trench portion 40, it is possible to reduce the electric field strength at the end portions of the extension parts 41. The gate metal layer 50 may be electrically connected to the gate conductive portion, via the connection portion 25, in the connection part 43 of the gate trench portion 40.

The dummy trench portion 30 is an example of the plurality of trench portions extending in a predetermined extension direction on the front surface 21 side of the semiconductor substrate 10. The dummy trench portion 30 is a trench portion which is electrically connected to the emitter electrode 52. Similarly to the gate trench portions 40, the dummy trench portions 30 are arrayed at a predetermined interval along a predetermined array direction (the X axis direction in the present example). The dummy trench portion 30 in the present example has an I shape on the front surface 21 of the semiconductor substrate 10, but may have a U shape on the front surface 21 of the semiconductor substrate 10 similar to the gate trench portion 40. That is, the dummy trench portion 30 may have two extension parts 31 which extend along the extension direction, and a connection part 33 which connects the two extension parts, as described below.

The transistor portion 70 in the present example has a structure in which two gate trench portions 40 and two dummy trench portions 30 are repetitively arrayed. That is, the transistor portion 70 in the present example has the gate trench portions 40 and the dummy trench portions 30 at a ratio of 1:1. For example, the transistor portion 70 has one dummy trench portion 30 between two extension parts 41.

It is to be noted that the ratio between the gate trench portions 40 and the dummy trench portions 30 is not limited to that in the present example. The ratio of the gate trench portions 40 may be greater than the ratio of the dummy trench portions 30, or the ratio of the dummy trench portions 30 may be greater than the ratio of the gate trench portions 40. The ratio between the gate trench portions 40 and the dummy trench portions 30 may be 2:3, or may be 2:4. In addition, the transistor portion 70 may not have the dummy trench portion 30 with all trench portions being the gate trench portions 40.

The well region 17 is a region of the second conductivity type which is provided to be closer to the front surface 21 side of the semiconductor substrate 10 than a drift region 18 which will be described below. The well region 17 is an example of a well region provided on a periphery side of the active region. The well region 17 is of the P+ type as an example. The well region 17 is formed in a predetermined range from an end portion of an active region on a side where the gate metal layer 50 is provided. A diffusion depth of the well region 17 may be deeper than depths of the gate trench portion 40 and the dummy trench portion 30. Partial regions of the gate trench portion 40 and the dummy trench portion 30 on a gate metal layer 50 side are formed in the well region 17. Bottoms of ends of the gate trench portion 40 and the dummy trench portion 30 in the extension direction may be covered with the well region 17.

The contact hole 54 is formed above the emitter region 12 in the transistor portion 70. The contact hole 54 is not provided above well regions 17 provided at both ends in the Y axis direction. One or more contact holes 54 may be formed to pass through the interlayer dielectric film into an inside of the semiconductor substrate 10. The one or more contact holes 54 may be provided to extend in the extension direction, or may be provided to extend in a direction different from the extension direction.

A trench contact portion 26 is provided in the contact hole 54. The trench contact portion 26 is provided to pass through the front surface 21 of the semiconductor substrate 10, from an upper surface of the interlayer dielectric film into the inside of the semiconductor substrate 10. The trench contact portion 26 contains a conductive material with which the contact hole 54 is filled. The trench contact portion 26 may contain the same material as that of the emitter electrode 52. The trench contact portion 26 may include a tungsten plug, and may include a barrier metal such as Ti or TiN. The trench contact portion 26 has a main trench contact 27 and a sub-trench contact 28.

The main trench contact 27 is provided to extend in the trench extension direction of the plurality of trench portions in a top view. The main trench contact 27 will be described in detail below.

The sub-trench contact 28 is provided to extend from the main trench contact 27 in a direction different from the trench extension direction in the top view. The sub-trench contact 28 may be provided to extend in the trench array direction of the plurality of trench portions, or may be provided to extend in a direction having a predetermined angle with respect to the trench array direction. The sub-trench contacts 28 may be provided such that the respective sub-trench contacts 28 extends in directions different from each other. The sub-trench contact 28 may have a curved portion.

The sub-trench contact 28 may be provided across the main trench contact 27 in the trench array direction. The sub-trench contact 28 is provided not to contact an adjacent trench portion. This makes it possible to prevent a short circuit between the emitter electrode 52 and the gate metal layer 50.

A plurality of sub-trench contacts 28 may be provided for the main trench contact 27, in a mesa portion 71. The plurality of sub-trench contacts 28 are provided above the emitter region 12 extending in the trench extension direction of the plurality of trench portions. By providing the sub-trench contact 28 above the emitter region 12, it is possible to adjust an area of the emitter region 12 at the front surface 21 of the semiconductor substrate 10, and adjust a saturation current of the semiconductor device 100.

A plug region 73 (described below) is provided on a lower surface of the trench contact portion 26. By providing the plug region 73 on the lower surface of the trench contact portion 26, it is possible to extract holes from the semiconductor substrate 10, and enhance latch-up resistance of the semiconductor device 100.

The mesa portion 71 is a mesa portion provided to be adjacent to the trench portion in a plane parallel to the front surface 21 of the semiconductor substrate 10. The mesa portion may be a part of the semiconductor substrate 10 sandwiched between two trench portions that are adjacent to each other, and may be a part from the front surface 21 of the semiconductor substrate 10 to a depth of a lowermost bottom portion of each trench portion. An extension part of each trench portion may be defined as one trench portion. That is, the region sandwiched between two extension parts may be defined as a mesa portion.

The mesa portion 71 is provided to be adjacent to at least one of the dummy trench portion 30 or the gate trench portion 40, in the transistor portion 70. The mesa portion 71 has the well region 17, the emitter region 12, and the base region 14, at the front surface 21 of the semiconductor substrate 10. In the mesa portion 71, the emitter region 12 is provided to extend in the trench extension direction of the plurality of trench portions.

The base region 14 is a region of the second conductivity type which is provided on the front surface 21 side of the semiconductor substrate 10. The base region 14 is of the P− type as an example. A doping concentration of the base region 14 may be 1E14 cm⁻³ or more, and 1E18 cm⁻³ or less. The base region 14 may be provided below the emitter region 12. The base region 14 is provided in contact with the gate trench portion 40. The base region 14 may be provided in contact with the dummy trench portion 30. The base regions 14 may be provided at both end portions of the mesa portion 71 in the Y axis direction, at the front surface 21 of the semiconductor substrate 10. It should be noted that FIG. 1A shows only one end portion of the base region 14 in the Y axis direction.

The emitter region 12 is a region of the first conductivity type which has a higher doping concentration than that of the drift region 18. The emitter region 12 in the present example is of the N+ type as an example. An example of a dopant of the emitter region 12 may be arsenic (As). The emitter region 12 is provided in contact with the gate trench portion 40, at the front surface 21 in the mesa portion 71. The emitter region 12 may be provided to extend in the X axis direction from one to another of two trench portions with the mesa portion 71 being sandwiched therebetween. The emitter region 12 may also be provided below the contact hole 54.

In addition, the emitter region 12 may be, or may not be in contact with the dummy trench portion 30. The emitter region 12 in the present example is in contact with the dummy trench portion 30.

In the semiconductor device 100 in the present example, a region of the second conductivity type which has a high concentration is not provided at the front surface 21 of the semiconductor substrate 10. In the semiconductor device 100 in the present example, over the entire region that operates as a transistor in the mesa portion 71, the emitter region 12 is provided at the front surface 21. By not providing the region of the second conductivity type, it is possible to enhance an operating efficiency of the semiconductor device 100. In addition, it is possible to enhance the saturation current when the semiconductor device 100 is reduced in size.

FIG. 1B shows an example of a cross section a-a′ in FIG. 1A. The cross section a-a′ is an XZ plane that does not pass through the sub-trench contact 28. The semiconductor device 100 in the present example has: the semiconductor substrate 10 provided with the emitter region 12, the base region 14, an accumulation region 16, the drift region 18, a buffer region 20, the collector region 22, and the plug region 73; the interlayer dielectric film 38; and the emitter electrode 52 and a collector electrode 24, in the cross section a-a′.

The drift region 18 is a region of the first conductivity type which is provided in the semiconductor substrate 10. The drift region 18 in the present example is of the N− type as an example. The drift region 18 may be a region which has remained without another doping region being formed in the semiconductor substrate 10. That is, the doping concentration of the drift region 18 may be a doping concentration in the semiconductor substrate 10.

The buffer region 20 is a region of the first conductivity type which is provided to be closer to a back surface 23 side of the semiconductor substrate 10 than the drift region 18. The buffer region 20 in the present example is of the N type as an example. A doping concentration of the buffer region 20 is higher than the doping concentration of the drift region 18. The buffer region 20 may function as a field stop layer which prevents a depletion layer extending from a lower surface side of the base region 14 from reaching the collector region 22 of the second conductivity type. It should be noted that the buffer region 20 may be omitted.

The collector region 22 is provided on a back surface 23 of the semiconductor substrate 10, in the transistor portion 70. The collector region 22 is a region of the second conductivity type which has a doping concentration higher than that of the base region 14. The collector region 22 in the present example is of the P+ type as an example.

The collector electrode 24 is an example of a metal layer on a back surface side which is provided in contact with the back surface 23 of the semiconductor substrate 10. The emitter electrode 52 is formed above the semiconductor substrate 10 and the interlayer dielectric film 38.

The accumulation region 16 is a region of the first conductivity type which is provided below the base region 14 in the depth direction of the semiconductor substrate 10, and which has a doping concentration higher than that of the drift region 18. The accumulation region 16 in the present example is of the N+ type as an example. By providing the accumulation region 16, it is possible to increase a carrier injection enhancement effect (IE effect), and an on voltage of the transistor portion 70.

One or more gate trench portions 40 and one or more dummy trench portions 30 are provided at the front surface 21. Each trench portion is provided from the front surface 21 to the drift region 18. In a region provided with at least any of the emitter region 12, the base region 14, or the accumulation region 16, each trench portion also passes through these regions to reach the drift region 18. A configuration in which a trench portion passes through a doping region is not limited to a configuration which is made by forming a doping region and then forming a trench portion in order. The configuration of the trench portion passing through the doping region includes a configuration of the doping region being formed between the trench portions after forming the trench portion.

The gate trench portion 40 has a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor at the inner wall of the gate trench. The gate conductive portion 44 is formed farther inward than the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region facing the base region 14 adjacent on a mesa portion 71 side with the gate dielectric film 42 being sandwiched therebetween, in the depth direction of the semiconductor substrate 10. When a predetermined voltage is applied to the gate conductive portion 44, a channel is formed by an electron inversion layer in a surface layer of the base region 14 at a boundary in contact with the gate trench.

The dummy trench portion 30 may have the same structure as that of the gate trench portion 40. The dummy trench portion 30 has a dummy trench, a dummy dielectric film 32, and a dummy conductive portion 34 which are formed on the front surface 21 side. The dummy dielectric film 32 is formed to cover an inner wall of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 is covered with the interlayer dielectric film 38 on the front surface 21.

The interlayer dielectric film 38 is provided on the front surface 21. The emitter electrode 52 is provided above the interlayer dielectric film 38. The interlayer dielectric film 38 is provided with one or more trench contact portions 26 to electrically connect the emitter electrode 52 to the semiconductor substrate 10. That is, the trench contact portion 26 is provided in the mesa portion between the plurality of trench portions. Similarly to the trench contact portion 26, the contact hole 55 and the contact hole 56 may also be provided to pass through the interlayer dielectric film 38.

The main trench contact 27 electrically connects the emitter electrode 52 to the semiconductor substrate 10. In the depth direction of the semiconductor substrate 10, a depth of a lower end of the main trench contact 27 may be provided at a position deeper than a depth of a lower end of the emitter region 12, or may be the same as the depth of the lower end of the emitter region 12. The depth of the lower end of the main trench contact 27 may be provided at a shallower position than a depth of a lower end of the base region 14, and by providing the lower end of the main trench contact 27 at a deeper position than that of the lower end of the emitter region 12, it is possible to enhance latch-up resistance of the semiconductor device 100.

The main trench contact 27 may have a predetermined width in the trench array direction of the plurality of trench portions. In the present specification, the width of the main trench contact 27 may be a width at the lower end of the main trench contact 27, or may be a width from one side wall to another side wall of the main trench contact 27 at the front surface 21 of the semiconductor substrate 10, or may be an opening width of the contact hole 54 at an upper end of the interlayer dielectric film 38. The width of the main trench contact 27 may be a width from one side wall to another side wall of the main trench contact 27 at any depth, in the trench array direction of the plurality of trench portions. In the present example, a width W27 of the main trench contact 27 is a width at the lower end of the main trench contact 27.

In an example, the width of the main trench contact 27 in the trench array direction of the plurality of trench portions is the same as a width of the sub-trench contact 28 in the trench extension direction of the plurality of trench portions, which will be described below. The width of the main trench contact 27 in the trench array direction of the plurality of trench portions may be greater, or may be smaller than the width of the sub-trench contact 28 in the trench extension direction of the plurality of trench portions. The width of the main trench contact 27 in the trench array direction of the plurality of trench portions may be 0.1 μm or more, and may be 0.8 μm or less. By adjusting the width of the main trench contact 27, it is possible to adjust embeddability of a tungsten plug which is embedded in the contact hole 54.

The plug region 73 is a region of the second conductivity type which is provided in contact with the lower end of the trench contact portion 26. A doping concentration of the plug region 73 is higher than the doping concentration of the base region 14. The plug region 73 in the present example is of the P+ type as an example. The doping concentration of the plug region 73 may be 1E17 cm⁻³ or more, and may be 1E20 cm⁻³ or less.

The plug region 73 may be provided to cover a bottom portion and a part of the side wall of the trench contact portion 26. The plug region 73 may be provided to be spaced apart from the emitter region 12, or may be provided in contact with the emitter region 12. The plug region 73 in the present example is provided in contact with the emitter region 12. By providing the plug region 73 on the lower surface of the trench contact portion 26, it is possible to enhance latch-up resistance of the semiconductor device 100.

The plug region 73 may be provided to be spaced apart from an adjacent trench portion in the trench array direction of the plurality of trench portions. The plug region 73 may be provided to be spaced apart from the gate trench portion 40. In this manner, a gate voltage required to form a channel inversion region becomes constant, which makes it possible for a characteristic of the semiconductor device 100 to be uniform.

The plug region 73 may be formed by implanting the dopant via the contact hole 54. The plug region 73 may be provided on lower surfaces of both of the main trench contact 27 and the sub-trench contact 28. In addition, the plug region 73 may be provided first, and then the trench contact portion 26 having the main trench contact 27 and the sub-trench contact 28 may be provided.

FIG. 1C shows an example of a cross section b-b′ in FIG. 1A. The cross section b-b′ is the XZ plane that passes through the main trench contact 27 and the sub-trench contact 28. A difference from the cross section shown in FIG. 1B will be described with reference to FIG. 1C.

The sub-trench contact 28 electrically connects the emitter electrode 52 to the semiconductor substrate 10. In the depth direction of the semiconductor substrate 10, a depth of a lower end of the sub-trench contact 28 may be the same as the depth of the lower end of the main trench contact 27. In FIG. 1C, the position of the main trench contact 27 is shown by a dotted line for the purpose of illustration.

The plug region 73 is also provided below the sub-trench contact 28. The plug region 73 may cover a bottom surface and a part of a side wall of the sub-trench contact 28. By providing the sub-trench contact 28 to adjust the area of the emitter region 12 at the front surface 21 of the semiconductor substrate 10, and to adjust the saturation current of the semiconductor device 100, and by providing the plug region 73 below the sub-trench contact 28, it is possible to enhance latch-up resistance of the semiconductor device 100.

The sub-trench contact 28 is provided to be spaced apart from the trench portion, in the trench array direction of the plurality of trench portions. In an example, the sub-trench contact 28 is provided to have a predetermined distance dx from an adjacent trench portion, in the trench array direction. The predetermined distance dx may be a shortest distance between the sub-trench contact 28 and the trench portion in the present example. In the present example, the shortest distance between the sub-trench contact 28 and the trench portion is a distance from a side wall of the adjacent trench portion, to a side wall of the sub-trench contact 28 on an upper surface of the interlayer dielectric film 38.

When the side wall of the sub-trench contact 28 does not have a tapering shape, the shortest distance between the sub-trench contact 28 and the trench portion may be a distance from the side wall of the adjacent trench portion, to the side wall of the sub-trench contact 28, at the same depth.

When the side wall of the sub-trench contact 28 has an inverse tapering shape, the shortest distance between the sub-trench contact 28 and the trench portion may be a distance from the side wall of the adjacent trench portion, to a lower end of the side wall of the sub-trench contact 28.

The shortest distance between the sub-trench contact 28 and the trench portion may be 0.1 μm or more, and may be 0.7 μm or less, in the trench array direction of the plurality of trench portions. By providing the sub-trench contact 28 to have the predetermined distance dx, even in a case where a misalignment occurs when the trench contact portion 26 is formed, it is possible to prevent a short circuit between the emitter electrode 52 and the gate metal layer 50.

FIG. 1D shows an example of a cross section c-c′ in FIG. 1A. The cross section c-c′ is a YZ plane along the main trench contact 27. The main trench contact 27 in the present example is provided to a position deeper than the depth of the lower end of the emitter region 12, and thus the emitter region 12 is not shown in the cross section shown in FIG. 1D.

The plug region 73 is provided, along the main trench contact 27, to extend in the trench extension direction of the plurality of trench portions. The plug region 73 may be discretely provided to cover a part of a lower surface of the main trench contact 27, or may be continuously provided to cover the entire lower surface of the main trench contact 27. By covering the lower surface of the main trench contact 27 with the plug region 73, it is possible to enhance latch-up resistance of the semiconductor device 100 without reducing a part of the semiconductor device 100 which performs the transistor operation.

FIG. 1E shows an example of a cross section d-d′ in FIG. 1A. The cross section d-d′ is the YZ plane that does not pass through the main trench contact 27, but passes through the sub-trench contact 28.

The plurality of sub-trench contacts 28 are provided at a predetermined interval d28, in the trench extension direction of the plurality of trench portions. The predetermined interval d28 may be 0.1 μm or more, and may be 5.0 μm or less. By adjusting the interval at which the plurality of sub-trench contacts 28 are provided, it is possible to adjust the saturation current of the semiconductor device 100.

The plurality of sub-trench contacts 28 have a predetermined width W28 in the trench extension direction of the plurality of trench portions. In the present specification, the width of the sub-trench contact 28 may be a width at the lower end of the sub-trench contact 28, or may be a width from one side wall to another side wall of the sub-trench contact 28 at the front surface 21 of the semiconductor substrate 10, or may be the opening width of the contact hole 54 at the upper end of the interlayer dielectric film 38. The width of the sub-trench contact 28 may be a width from one side wall to another side wall of the sub-trench contact 28 at any depth, in the trench extension direction of the plurality of trench portions. In the present example, the width W28 of the sub-trench contact 28 is a width at the lower end of the sub-trench contact 28.

The width W28 of the sub-trench contact 28 in the trench extension direction of the plurality of trench portions may be the same as, or may be different from the width W27 of the main trench contact 27 in the trench array direction of the plurality of trench portions. The width W28 of the sub-trench contact 28 in the trench extension direction of the plurality of trench portions may be 90% or more, and may be 110% or less of the width W27 of the main trench contact 27 in the trench array direction of the plurality of trench portions.

The width W28 of the sub-trench contact 28 may be 0.1 μm or more, and may be 0.8 μm or less in the trench extension direction of the plurality of trench portions. By adjusting the width W28 of the sub-trench contact 28, it is possible to adjust embeddability of a tungsten plug which is embedded in the contact hole 54.

The plug region 73 is provided to have a predetermined distance d73 in the trench extension direction of the plurality of trench portions. The predetermined distance d73 may be 0.1 μm or more, and may be 0.5 μm or less. In the present example, the plug regions 73 respectively provided on the lower surfaces of the sub-trench contacts 28 which are adjacent to each other, are provided not to come into contact with each other in the trench extension direction of the plurality of trench portions.

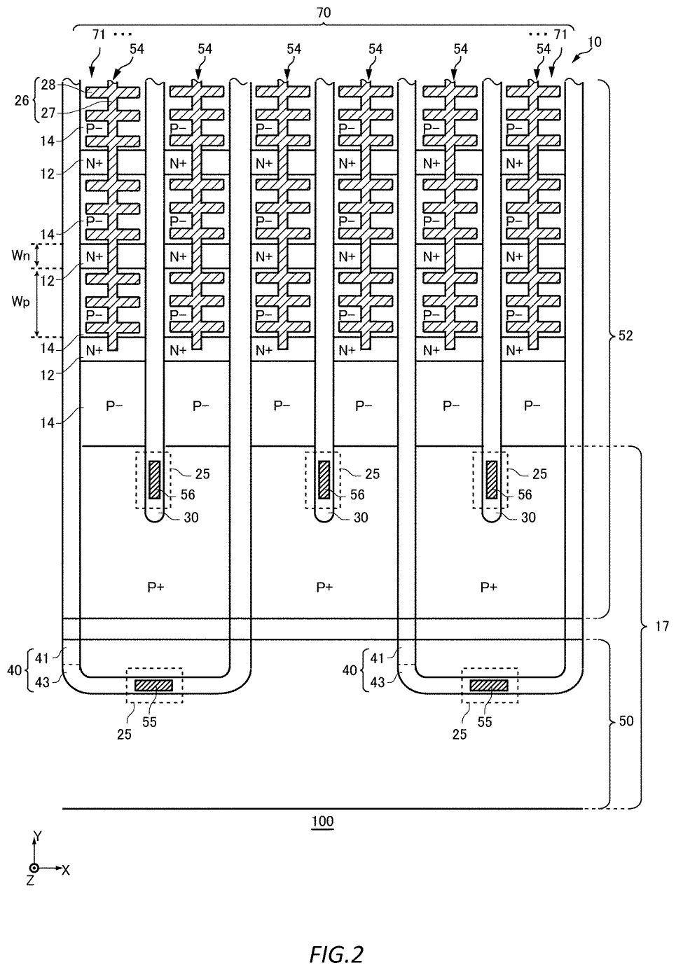

FIG. 2 is a view showing a modified example of the upper surface of the semiconductor device 100. A difference from the semiconductor device 100 shown in FIG. 1A will be described with reference to FIG. 2.

In the example of the upper surface shown in FIG. 2, in a region that operates as a transistor, as well, in the mesa portion 71, the base region 14 is provided. That is, in the mesa portion 71, the emitter region 12 and the base region 14 may be alternately provided at the front surface 21 of the semiconductor substrate 10 in the trench extension direction of the plurality of trench portions.

In the mesa portion 71, the emitter region 12 and the base region 14 may be provided to have predetermined widths Wn and Wp. For the respective emitter regions 12 and the respective base regions 14 which are discretely provided, the widths Wn and Wp may be the same as, or may be different from each other. The widths Wn and Wp may be the same as, or may be different from each other.

A ratio Wn:Wp between the widths Wn and Wp may be set to any ratio from 3:1 to 1:8. In the present example, the ratio Wn:Wp between the widths Wn and Wp is approximately 1:3. By adjusting the ratio of the widths Wn and Wp, it is possible to adjust the saturation current of the semiconductor device 100 according to a required characteristic.

The main trench contact 27 is provided to extend in the trench extension direction, above the emitter region 12 and the base region 14 which are alternately provided in the trench extension direction. The main trench contact 27 is provided to extend into insides of the emitter region 12 and the base region 14 in the depth direction of the semiconductor substrate 10, and electrically connects the emitter region 12 and the base region 14 to the emitter electrode 52.

The sub-trench contact 28 is provided above the base region 14. The sub-trench contact 28 is not provided above the emitter region 12. The region where the base region 14 is provided at the front surface 21 of the semiconductor substrate 10 is a region that does not perform the transistor operation, and thus by providing the sub-trench contact 28 in this way, it is possible to enhance latch-up resistance of the semiconductor device 100 without reducing an operating efficiency.

In the example of the upper surface shown in FIG. 2, in a region that operates as a transistor in the mesa portion 71, no region of the second conductivity type other than the base region 14 is provided. This eliminates a need for an ion implantation step for separately forming the region of the second conductivity type, which makes it possible to reduce a manufacturing cost of the semiconductor device 100.

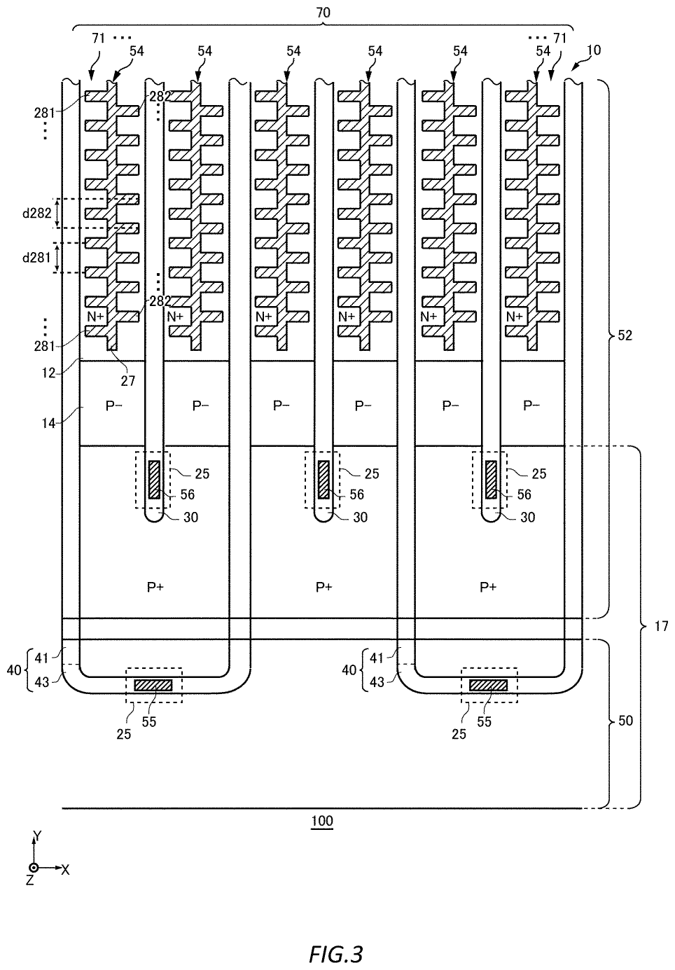

FIG. 3 is a view showing a modified example of the upper surface of the semiconductor device 100. A difference from the semiconductor device 100 shown in FIG. 1A will be described with reference to FIG. 3.

The plurality of trench portions may include a first trench portion, and a second trench portion which is adjacent to the first trench portion. In an example, the first trench portion is the gate trench portion 40 and the second trench portion is the dummy trench portion 30. The first trench portion may be the dummy trench portion 30, and the second trench portion may be the gate trench portion 40.

The plurality of sub-trench contacts 28 may include a first sub-trench contact 281 which extends from the main trench contact 27 toward the first trench portion in the trench array direction of the plurality of trench portions, and which terminates without reaching the first trench portion. The plurality of sub-trench contacts 28 may include a second sub-trench contact 282 which extends from the main trench contact 27 toward the second trench portion in the trench array direction of the plurality of trench portions, and which terminates without reaching the second trench portion.

The first sub-trench contacts 281 may be provided to have a predetermined interval d281, in the trench extension direction of the plurality of trench portions. The second sub-trench contacts 282 may be provided to have a predetermined interval d282 in the trench extension direction of the plurality of trench portions. The interval d281 and the interval d282 may be the same as, or may be different from each other. The first sub-trench contacts 281 and the second sub-trench contacts 282 may be provided in equal numbers, or may be provided in different numbers.

The first sub-trench contacts 281 and the second sub-trench contacts 282 may be alternately provided in the trench extension direction of the plurality of trench portions. In the trench extension direction of the plurality of trench portions, one second sub-trench contact 282 may be provided between two first sub-trench contacts 281, or one first sub-trench contact 281 may be provided between two second sub-trench contacts 282.

The first sub-trench contact 281 may be provided at a position that internally divides, at any ratio, the interval d282 between two second sub-trench contacts 282 that are adjacent to each other. In the present example, the first sub-trench contact 281 is provided at a midpoint of the interval d282 between two second sub-trench contacts 282 that are adjacent to each other.

The second sub-trench contact 282 may be provided at a position that internally divides, at any ratio, the interval d281 between two first sub-trench contacts 281 that are adjacent to each other. In the present example, the second sub-trench contact 282 is provided at a midpoint of the interval d281 between two first sub-trench contacts 281 that are adjacent to each other.

The first sub-trench contact 281 and the second sub-trench contact 282 may be provided at symmetrical positions with the main trench contact 27 sandwiched therebetween. In this case, the first sub-trench contact 281 and the second sub-trench contact 282 may be connected to be treated as one sub-trench contact 28. By adjusting the positions, the number, and the interval, at which the first sub-trench contacts 281 and the second sub-trench contacts 282 are provided, it is possible to adjust the saturation current of the semiconductor device 100 according to a required performance.

The first sub-trench contact 281 and the second sub-trench contact 282 may also be provided with the plug region 73. This makes it possible to enhance latch-up resistance of the semiconductor device 100.

The modified example shown in FIG. 3 may be combined with the modified example shown in FIG. 2. That is, in the Example in which the emitter region 12 and the base region 14 are alternately provided at the front surface 21 of the semiconductor substrate 10 in the trench extension direction of the plurality of trench portions, the first sub-trench contact 281 and the second sub-trench contact 282 may be provided above the base region 14, and may not be provided above the emitter region 12.

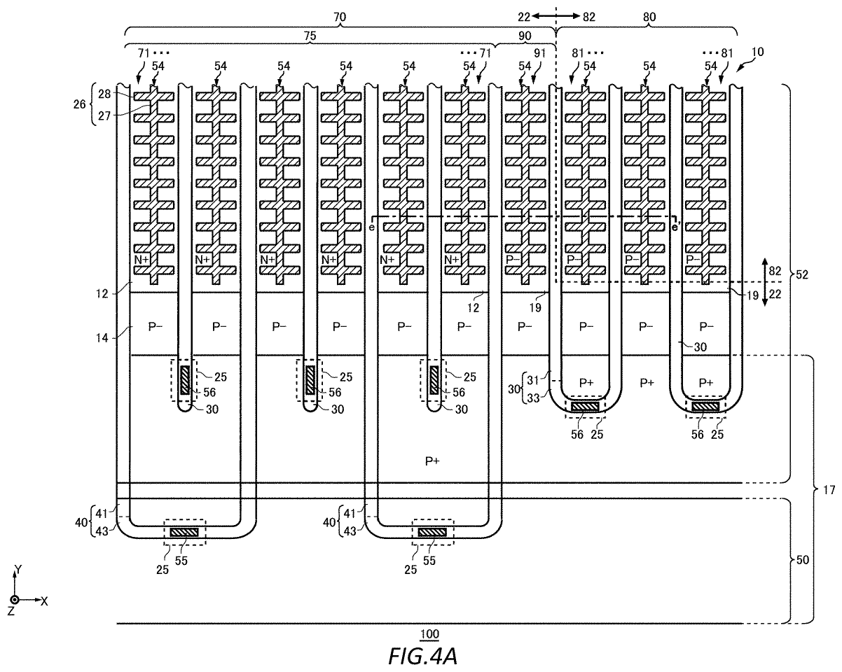

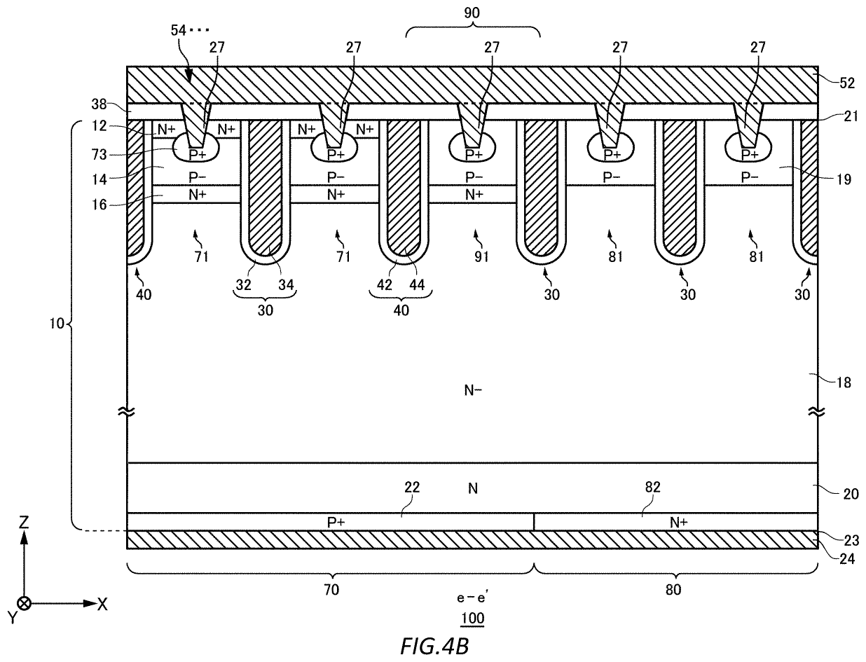

FIG. 4A is a view showing a modified example of the upper surface of the semiconductor device 100. The semiconductor device 100 in the present example is an RC-IGBT which further includes a diode portion 80 which has an anode region 19 at the front surface 21 of the semiconductor substrate 10.

The diode portion 80 is a region obtained by projecting a cathode region 82 provided on the back surface 23 side of the semiconductor substrate 10 onto the upper surface of the semiconductor substrate 10. At the back surface 23 of the semiconductor substrate 10, the collector region 22 may be provided in a region other than the cathode region 82.

The anode region 19 is a region of the second conductivity type provided at the front surface 21 of the semiconductor substrate 10. The anode region 19 in the present example is of the P− type as an example. A doping concentration of the anode region 19 may be the same as, or may be different from the doping concentration of the base region 14. The doping concentration of the anode region 19 may be 1E15 cm⁻³ or more, and may be 1E18 cm⁻³ or less.

A mesa portion 81 is a mesa portion provided to be adjacent to the trench portion in a plane parallel to the front surface 21 of the semiconductor substrate 10. The mesa portion 81 is provided to be adjacent to two dummy trench portions 30, in the diode portion 80. The mesa portion 81 has the well region 17, the base region 14, and the anode region 19, at the front surface 21 of the semiconductor substrate 10. In the mesa portion 81, the anode region 19 is provided to extend in the trench extension direction of the plurality of trench portions.

The transistor portion 70 in the present example includes a main region 75, and a boundary portion 90 which is positioned in a boundary between the transistor portion 70 and the diode portion 80. It is to be noted that the semiconductor device 100 may not include the boundary portion 90.

In the transistor portion 70, the main region 75 may be a region other than the boundary portion 90. The main region 75 has a channel region formed during an operation of the semiconductor device 100, and functions as an active region.

The boundary portion 90 is a region which is provided in the transistor portion 70, and which is adjacent to the diode portion 80. The boundary portion 90 has the anode region 19 at the front surface 21 of the semiconductor substrate 10. The boundary portion 90 in the present example does not have the emitter region 12. The trench portion in the boundary portion 90 may be the gate trench portion 40, or may be the dummy trench portion 30. The boundary portion 90 may be arranged such that both ends in the X axis direction are the dummy trench portions 30.

A mesa portion 91 is a mesa portion provided to be adjacent to the trench portion in a plane parallel to the front surface 21 of the semiconductor substrate 10.

The mesa portion 91 is provided to be adjacent to at least one of the dummy trench portion 30 or the gate trench portion 40, in the transistor portion 70. In the present example, a structure of the mesa portion 91 at the front surface 21 of the semiconductor substrate 10 is the same as the structure of the mesa portion 81 at the front surface 21 of the semiconductor substrate 10.

The contact hole 54 may also be provided above the diode portion 80 and the boundary portion 90. That is, the trench contact portion 26 may be provided above the diode portion 80 and the boundary portion 90, and the main trench contact 27 and the sub-trench contact 28 may be provided above the anode region 19. By providing the main trench contact 27 and the sub-trench contact 28 above the diode portion 80, it is possible to enhance a contact property in the diode portion 80, and enhance a forward voltage Vf of the diode portion 80.

Above the diode portion 80, only the main trench contact 27 may be provided, and the sub-trench contact 28 may not be provided. This eliminates a need for a tungsten plug for forming the sub-trench contact 28, which makes it possible to reduce a manufacturing cost of the semiconductor device 100.

FIG. 4B shows an example of a cross section e-e′ in FIG. 4A. The cross section e-e′ is the XZ plane that does not pass through the sub-trench contact 28. A difference from the cross section shown in FIG. 1B will be described with reference to FIG. 4B.

The plug region 73 is also provided in the diode portion 80 and the boundary portion 90. The plug region 73 is provided on the lower surface of the trench contact portion 26, in the diode portion 80 and the boundary portion 90. That is, the plug region 73 may be provided to cover the bottom portions and parts of the side walls of the main trench contact 27 and the sub-trench contact 28, in the diode portion 80 and the boundary portion 90.

The plug region 73 may be provided continuously in the trench extension direction of the plurality of trench portions, or may be provided discretely, in the diode portion 80 and the boundary portion 90. By providing the plug region 73 in the diode portion 80 and the boundary portion 90, it is possible to enhance an efficiency of extracting holes from the semiconductor substrate 10, and enhance latch-up resistance of the semiconductor device 100.

The accumulation region 16 may also be provided in the diode portion 80. In the present example, the accumulation region 16 is provided in the boundary portion 90, and is not provided in the diode portion 80.

The modified examples shown in FIG. 4A and FIG. 4B may also be combined with the modified example shown in FIG. 2 or the modified example shown in FIG. 3, or both of those modified examples. That is, in the semiconductor device 100 having the diode portion 80, in the transistor portion 70, the emitter region 12 and the base region 14 may be alternately provided at the front surface 21 of the semiconductor substrate 10 in the trench extension direction of the plurality of trench portions; and the sub-trench contact 28 may be provided above the base region 14, and may not be provided above the emitter region 12.

In the semiconductor device 100 including the diode portion 80, the first sub-trench contact 281 and the second sub-trench contact 282 may be provided. In the semiconductor device 100 having the diode portion 80, in the transistor portion 70, the emitter region 12 and the base region 14 may be alternately provided at the front surface 21 of the semiconductor substrate 10 in the trench extension direction of the plurality of trench portions; and the first sub-trench contact 281 and the second sub-trench contact 282 may be provided above the base region 14, and may not be provided above the emitter region 12.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the description of the claims that embodiments added with such alterations or improvements can be included in the technical scope of the present invention.

Note that the operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, the specification, or the drawings for the sake of convenience, it does not necessarily mean that the process must be performed in this order.

### EXPLANATION OF REFERENCES

10: semiconductor substrate; 12: emitter region; 14: base region; 16: accumulation region; 17: well region; 18: drift region; 19: anode region; 20: buffer region; 21: front surface; 22: collector region; 23: back surface; 24: collector electrode; 25: connection portion; 26: trench contact portion; 27: main trench contact; 28: sub-trench contact; 30: dummy trench portion; 31: extension part; 32: dummy dielectric film; 33: connection part; 34: dummy conductive portion; 38: interlayer dielectric film; 40: gate trench portion; 41: extension part; 42: gate dielectric film; 43: connection part; 44: gate conductive portion; 50: gate metal layer; 52: emitter electrode; 54: contact hole; 55: contact hole; 56: contact hole; 70: transistor portion; 71: mesa portion; 73: plug region; 75: main region; 80: diode portion; 81: mesa portion; 82: cathode region; 90: boundary portion; 91: mesa portion; 100: semiconductor device; 281: first sub-trench contact; 282: second sub-trench contact.

What is claimed is:

1. A semiconductor device comprising:
a drift region of a first conductivity type which is provided in a semiconductor substrate;
an emitter region of the first conductivity type which is provided at a front surface of the semiconductor substrate, and which has a doping concentration higher than that of the drift region;
a plurality of trench portions which are provided above the drift region;
a trench contact portion which is provided in a mesa portion between the plurality of trench portions; and
a plug region of a second conductivity type which is provided in contact with a lower end of the trench contact portion, wherein
the trench contact portion has
a main trench contact which extends in a trench extension direction in a top view, and
a sub-trench contact which extends from the main trench contact in a direction different from the trench extension direction in the top view.

2. The semiconductor device according to claim 1, wherein
a width of the main trench contact in a trench array direction of the plurality of trench portions is 0.1 μm or more, and 0.8 μm or less.

3. The semiconductor device according to claim 1, wherein
the sub-trench contact is provided across the main trench contact, in a trench array direction of the plurality of trench portions.

4. The semiconductor device according to claim 1, wherein
a plurality of sub-trench contacts are provided for the main trench contact, in the mesa portion.

5. The semiconductor device according to claim 4, wherein
the plurality of sub-trench contacts are provided above the emitter region extending in the trench extension direction of the plurality of trench portions.

6. The semiconductor device according to claim 4, wherein
the plurality of sub-trench contacts are provided at a predetermined interval, in the trench extension direction of the plurality of trench portions.

7. The semiconductor device according to claim 6, wherein
the interval is 0.1 μm or more, and 5.0 μm or less.

8. The semiconductor device according to claim 1, comprising:
a base region of the second conductivity type which is provided above the drift region, wherein
in the mesa portion, the emitter region and the base region are alternately provided at the front surface of the semiconductor substrate in the trench extension direction.

9. The semiconductor device according to claim 8, wherein
the main trench contact is provided to extend in the trench extension direction, above the emitter region and the base region which are alternately provided in the trench extension direction.

10. The semiconductor device according to claim 8, wherein
the sub-trench contact is provided above the base region.

11. The semiconductor device according to claim 4, wherein
the plurality of trench portions includes a first trench portion, and a second trench portion which is adjacent to the first trench portion, and
the plurality of sub-trench contacts include
a first sub-trench contact which extends from the main trench contact toward the first trench portion in a trench array direction of the plurality of trench portions, and which terminates without reaching the first trench portion, and
a second sub-trench contact which extends from the main trench contact toward the second trench portion in the trench array direction of the plurality of trench portions, and which terminates without reaching the second trench portion.

12. The semiconductor device according to claim 1, wherein
the semiconductor device being an RC-IGBT which further includes a diode portion.

13. The semiconductor device according to claim 12, wherein
the diode portion has an anode region of the second conductivity type which is provided at the front surface of the semiconductor substrate, and
the main trench contact and the sub-trench contact are provided above the anode region.

14. The semiconductor device according to claim 1, wherein
a width of the sub-trench contact is 0.1 μm or more, and 0.8 μm or less, in the trench extension direction of the plurality of trench portions.

15. The semiconductor device according to claim 1, wherein
a width of the sub-trench contact in the trench extension direction of the plurality of trench portions is 90% or more, and 110% or less of the width of the main trench contact in the trench array direction of the plurality of trench portions.

16. The semiconductor device according to claim 1, wherein
a shortest distance between the sub-trench contact and one trench portion of the plurality of trench portions is 0.1 μm or more, and 0.7 μm or less, in the trench array direction of the plurality of trench portions.

17. The semiconductor device according to claim 1, comprising:
an interlayer dielectric film which is provided above the semiconductor substrate, wherein
the main trench contact and the sub-trench contact are provided to pass through the front surface of the semiconductor substrate, from a contact hole provided in the interlayer dielectric film into an inside of the semiconductor substrate.

18. The semiconductor device according to claim 1, comprising:
a base region of the second conductivity type which is provided above the drift region, wherein
in the mesa portion, the emitter region and the base region are alternately provided at the front surface of the semiconductor substrate in the trench extension direction, and
a plurality of sub-trench contacts are provided in the base region exposed to the front surface of the semiconductor substrate.

19. The semiconductor device according to claim 1, wherein
a position of the lower end of the trench contact portion is deeper than a position of a lower end of the emitter region, in a depth direction of the semiconductor substrate.

20. The semiconductor device according to claim 1, comprising:
a base region of the second conductivity type which is provided above the drift region, wherein
the mesa portion has base regions of the second conductivity type at both ends in the trench extension direction,
in the mesa portion, the emitter region is provided to extend from one of base regions to another of the base regions in the trench extension direction, and
the trench contact portion is provided in the emitter region exposed to the front surface of the semiconductor substrate.
